(19) United States
(12) Patent Application Publication
(10) Pub. No.: US 2003/0113973 A1
(43) Pub. Date: Jun. 19, 2003

(54) Method for fabricating local interconnects

(76) Inventor: Tung-Yuan Chu, Tao-Yuan Hsien (TW)

Correspondence Address: NAIPO (NORTH AMERICA INTERNATIONAL PATENT OFFICE), P.O. BOX 506, MERRIFIELD, VA, 22116, US

(21) Appl. No.: 09/683,341

(22) Filed: Dec. 17, 2001

(51) Int. Cl. H01L 21/336

(52) U.S. Cl. 438/296; 438/279

(57) ABSTRACT

A local interconnect fabrication method is disclosed. A nitride spacer is formed on each sidewall of an etched recess formed across a shallow trench isolation region. The spacer prevents contact of metal with the exposed silicon substrate in the recess, and thus reduces leakage. High performance and low energy dissipation of devices can be achieved by reducing undesirable leakage current.

### BACKGROUND OF INVENTION

1. Field of the Invention

The present invention relates in general to the field of semiconductor device fabrication, and more particularly, to a method for reducing local interconnect leakage.

2. Description of the Prior Art

When the integration density of integrated circuits increases, the surface area of a chip available for forming interconnects becomes more and more limited due to the shrinking dimensions of devices. Local interconnects are an effective approach used to improve the integration of semiconductor devices by locally connecting a gate and a source/drain (S/D) region, or two source/drain regions, of two isolated metal-oxide-semiconductor (MOS) transistors.

Please refer to FIG. 1 through FIG. 4. FIG. 1 through FIG. 4 are schematic, cross-sectional diagrams depicting steps in a conventional method for fabricating a local interconnect.

Referring to FIG. 1, a semiconductor wafer 10 is first provided. The semiconductor wafer 10 comprises a silicon substrate 12, two adjacent MOS transistors 17 and 18 formed on the silicon substrate 12, and a shallow trench isolation (STI) region 14 used to isolate the two MOS transistors 17 and 18. The MOS transistor 17 comprises a gate 15 and a S/D region 14 located on one side of the STI region 14, while the MOS transistor 18 comprises a gate 19 and a S/D region 24 located on the other side of the STI region 14. A silicon nitride spacer 25 is formed on each sidewall of the gates 15 and 19. Silicide layer 26 is formed to reduce sheet resistance of the S/D regions 16 and 24. The S/D regions 16 and 24 have a predetermined junction depth, which is represented by “d” in FIG. 1.

Referring to FIG. 2, a silicon nitride layer 28 with a thickness of about 40 to about 300 angstroms (Å) is then deposited onto the semiconductor wafer 10 to cover the MOS transistors 17 and 18, as well as the STI region 14. The silicon nitride layer 28 acts as an etch stop layer in a subsequent process. An inter-layer dielectric (ILD) layer 30 having a thickness of about 5000 to 9000 angstroms (Å) is then deposited over the silicon nitride layer 28. A chemical mechanical polishing (CMP) is usually performed to planarize the ILD layer 30. A patterned photoresist layer 32 is formed on the ILD layer 30. The patterned photoresist layer 32 has an opening 34 to expose a portion of the underlying ILD layer 30. The opening 34 defines a local interconnect pattern.

Referring to FIG. 3, the exposed portions of the ILD layer 30 are anisotropically etched through the opening 34 by performing a first dry etching step. The first dry etching step stops at the silicon nitride layer 28.

Referring to FIG. 4, the silicon nitride layer 28 that is exposed by the first dry etching step is further etched away by a second dry etching step so as to expose the silicide layer 26 of the S/D regions 16 and 24. Typically, an etching selectivity of about 3:1 (etching rate of the silicon oxide:etching rate of the silicon nitride) is tuned for the second dry etching step. After finishing the second dry etching step, the photoresist layer 32 is stripped by a method known in the art and a local interconnect opening 35 is therefore transferred to the ILD layer 30. However, when etching the silicon nitride layer 28, the STI region 14 is also etched. After exposing the silicide layer 26 of the S/D regions 16 and 24 within the local interconnect opening 35, a recess 36 having a depth h is simultaneously created. When h>d, i.e. the recess 36 is deeper than the junction depth of the S/D regions 16 and 24, leakage occurs.

### SUMMARY OF INVENTION

It is therefore the primary objective of the present invention to provide a local interconnect method for reducing leakage.

In accordance with the objective of the present invention, one preferred embodiment of the invention includes the following steps. A silicon substrate having a first source/drain (S/D) region and a second S/D region laterally formed on the silicon substrate is provided. The second S/D region is adjacent to the first S/D region and isolated from the first S/D region by an isolation oxide region. An etch stop layer is deposited to cover the first S/D region, the second S/D region and the isolation oxide region. An interlayer dielectric (ILD) layer is formed over the etch stop layer. A resist layer is formed on the ILD layer. An opening is formed in the resist layer. The opening is positioned over the first S/D region, the second S/D region and the isolation oxide region. The ILD layer is etched away via the opening to the surface of the etch stop layer. The etch stop layer is subsequently etched away via the opening to expose the first and second S/D regions. A recess having a depth of h is simultaneously formed in the isolation oxide region after finishing the etching of the etch stop layer, thereby exposing a portion of the silicon substrate. The resist layer is stripped to leave a local interconnect opening in the ILD layer. A spacer layer is then deposited to cover bottom and interior walls of the recess and the exposed first and second S/D regions. The spacer layer is etched back to form a spacer on each wall of the recess.

It is an advantage of the present invention over the prior art method of forming a local interconnect that the spacer formed on each wall of the recess isolates the exposed sidewalls of the silicon substrate in the recess and thus blocks the leakage path for current.

### BRIEF DESCRIPTION OF DRAWINGS

FIG. 1 through FIG. 4 are schematic, cross-sectional diagrams depicting steps in a conventional method for fabricating a local interconnect.

FIG. 5 through FIG. 10 are schematic, cross-sectional diagrams depicting steps in a method according to the present invention for fabricating a local interconnect.

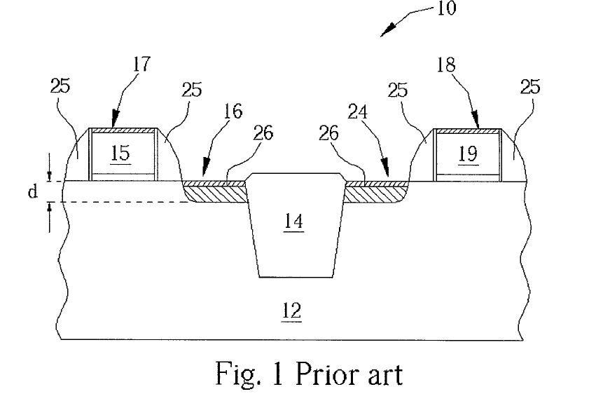

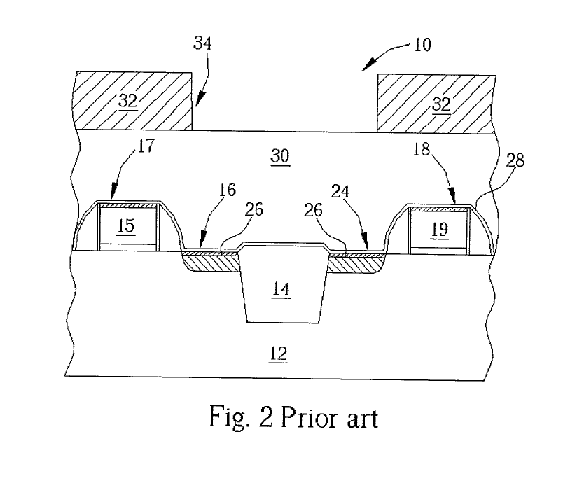

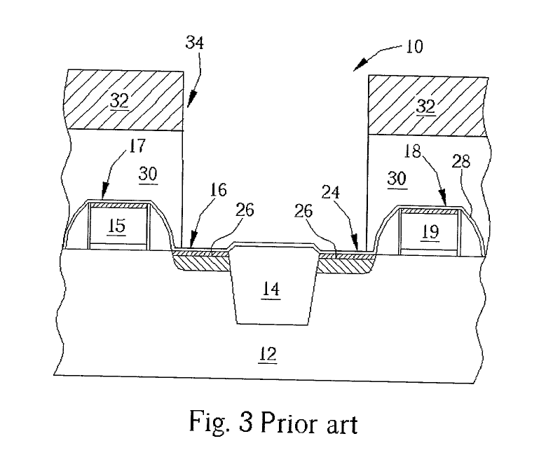

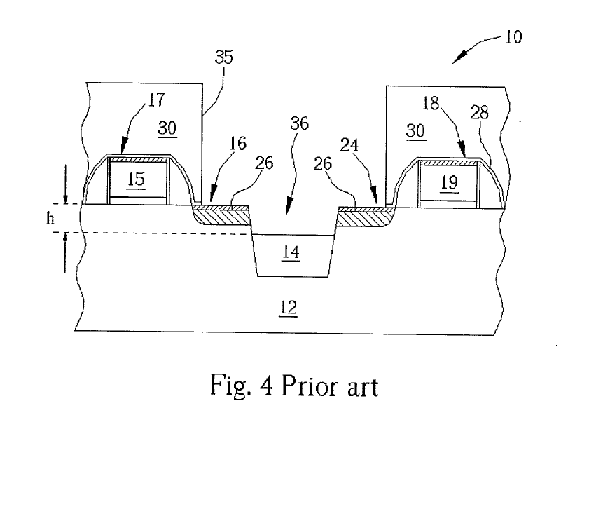

### DETAILED DESCRIPTION

Reference will now be made in detail to the preferred embodiment of the present invention, example of which is illustrated in the accompanying drawings.

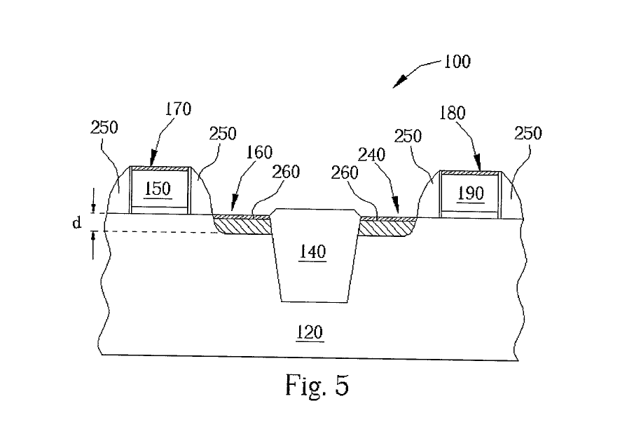

Please refer to FIG. 5 through FIG. 10. FIG. 5 through FIG. 10 are schematic, cross-sectional diagrams depicting steps in a method according to the present invention for fabricating a local interconnect.

Referring to FIG. 5, a semiconductor wafer 100 is provided. The semiconductor wafer 100 comprises a silicon substrate 120, two adjacent MOS transistors 170 and 180 formed on the silicon substrate 120, and a shallow trench isolation (STI) region 140 used to isolate the two MOS transistors 170 and 180. The MOS transistor 170 comprises a gate 150 and a S/D region 140 located on one side of the STI region 140, while the MOS transistor 180 comprises a gate 190 and a S/D region 240 located on the other side of the STI region 140. A silicon nitride spacer 250 is formed on each sidewall of the gates 150 and 190. A silicide layer or a self-aligned silicide (salicide) layer 260 is formed to reduce sheet resistance of the S/D regions 160 and 240. Similarly, the S/D regions 160 and 240 have a predetermined junction depth, which is represented by “d” as illustrated in FIG. 5.

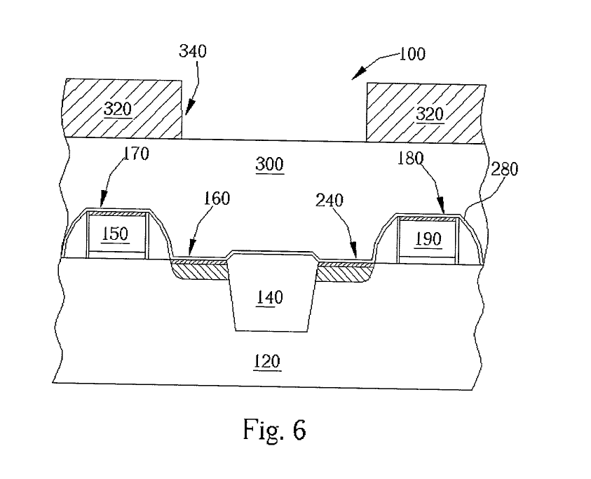

Referring to FIG. 6, a silicon nitride layer 280 with a thickness of about 40 to about 300 angstroms (Å) is deposited onto the semiconductor wafer 100 to cover the MOS transistors 170 and 180 as well as the STI region 140. The silicon nitride layer 280 acts as an etch stop layer in a subsequent process. An inter-layer dielectric (ILD) layer 300 having a thickness of about 5000 to 9000 angstroms (Å) is then deposited over the silicon nitride layer 280. The ILD layer 300 includes silicon oxide or borophosphosilicate (BPSG). A chemical mechanical polishing (CMP) is usually performed to planarize the ILD layer 300. A patterned photoresist layer 320 is then formed on the ILD layer 30. The patterned photoresist layer 320 has an opening 340 exposing a portion of the underlying ILD layer 300. The opening 340 defines a local interconnect pattern.

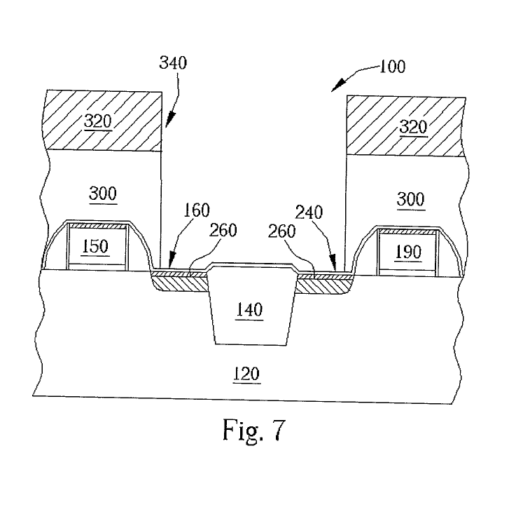

Referring to FIG. 7, the exposed portions of the ILD layer 300 are subsequently etched away via the opening 340 by using a first dry etching process. The first dry etching process terminates at the silicon nitride layer 280.

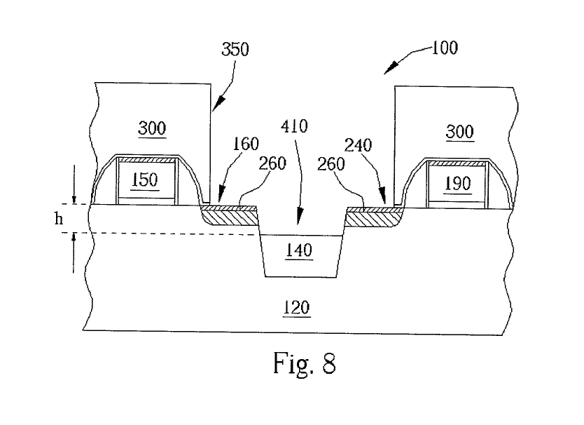

Referring to FIG. 8, the silicon nitride layer 280 that is exposed by the first dry etching step is further etched away by using a second dry etching step so as to expose the silicide layer 260 of the S/D regions 160 and 240. An etching selectivity of about 3:1 (etching rate of the silicon oxide:etching rate of the silicon nitride) is tuned for the second dry etching step. After finishing the second dry etching step, the photoresist layer 320 is stripped and a local interconnect opening 350 is formed in the ILD layer 30. When etching the silicon nitride layer 280, the STI region 140 is also etched. After exposing the suicide layer 260 of the S/D regions 160 and 240 within the local interconnect opening 350, a recess 410 having a depth of h is simultaneously created. As mentined, when h (recess depth)>d (junction depth), leakage occurs.

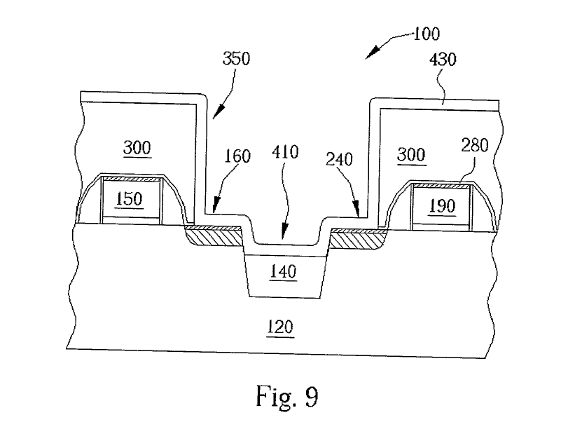

Referring to FIG. 9, a silicon nitride layer 430 is deposited over the semiconductor wafer 100 by, for example, chemical vapor deposition. The silicon nitride layer 430 covers the ILD layer 300, interior walls of the local interconnect opening 350, the S/D regions 160 and 240, and bottom and interior walls of the recess 410. Preferably, the thickness of the silicon nitride layer 430 is about 100 to 1000 angstroms (Å). Thereafter, an etch back process is performed to anisotropically etch the silicon nitride layer 430. After performing the etch back process, a nitride spacer 450 exists on each wall of the recess 410. At the same time, a spacer 460 is simultaneously formed on each wall of the local interconnect opening 350.

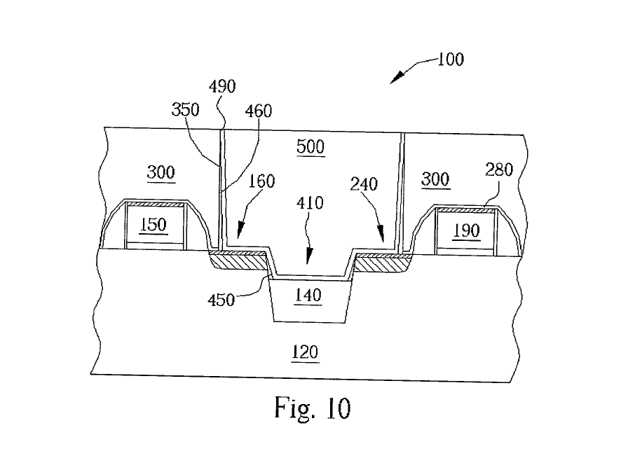

Referring to FIG. 10, a glue layer 490 having a thickness of about 100 to 150 angstroms (Å) is formed over the semiconductor wafer 100. The glue layer 490, which is used to improve adhesion between metal and dielectrics, may be made of TiN, Ti/TiN, TiW alloy, or the like. Thereafter, metallization is performed. Preferably, tungsten layer 500 is formed to fill the local interconnect opening 350 over the glue layer 490. The tungsten layer 500 is formed by, for example, low-pressure chemical vapor deposition (LPCVD). The thickness of the tungsten layer 500 is about 4000 to 7000 angstroms (Å). A CMP process is usually used to remove excess portions of the tungsten layer 500 outside the local interconnect opening 350.

In comparison with the prior art method, the present invention provides a method for fabricating local interconnects with higher reliability and lower leakage due to the use of a nitride spacer 450 on each sidewall of the etched recess 410. The spacer 450, which is formed after the etching of the etch stop layer 280, prevents the contact of metal filling the recess 410 with the exposed silicon substrate 100. High performance and low energy dissipation of devices can be achieved by reducing undesirable leakage current.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method for fabricating local interconnects, the method comprising:
providing a substrate having a first source/drain (S/D) region and a second S/D region laterally formed on the substrate, wherein the second S/D region is adjacent to the first S/D region and isolated from the first S/D region by an isolation region;
depositing an etch stop layer covering the first S/D region, the second S/D region and the isolation region;
depositing an interlayer dielectric (ILD) layer over the etch stop layer;
sequentially etching the ILD layer and the etch stop layer to form a local interconnect opening exposing portions of the first S/D region, the second S/D region and the isolation region, wherein a recess having a depth of h is formed in the isolation region after finishing the etch of the etch stop layer, thereby exposing a portion of the substrate;
depositing a spacer layer covering bottom and interior walls of the recess, and the exposed first and second S/D regions; and
etching back the spacer layer to form a spacer on each wall of the recess.

2. The method of claim 1 wherein after depositing the ILD layer, the method further comprises a polishing step to form a substantially even surface of the ILD layer.

3. The method of claim 1 wherein the isolation region comprises an STI oxide embedded in a trench.

4. The method of claim 1 wherein the first and second S/D regions both have a predetermined junction depth.

5. The method of claim 1 wherein each of the first and second S/D regions further comprises a salicide layer.

6. The method of claim 1 wherein the spacer layer is composed of silicon nitride.

7. The method of claim 1 wherein after forming the spacer, the method further comprises the following steps:
depositing a glue layer covering the spacer, the bottom of the recess, and the first and second S/D regions;
depositing a metal layer over the glue layer to fill the local interconnect opening; and
performing a chemical mechanical polishing (CMP) process to remove the metal layer and the glue layer above the ILD layer.

8. A method for fabricating local interconnects, the method comprising:
providing a substrate having a first source/drain (S/D) region and a second S/D region laterally formed on the substrate, wherein the second S/D region is adjacent to the first S/D region and isolated from the first S/D region by an isolation region;
depositing an interlayer dielectric (ILD) layer covering the first S/D region, the second S/D region and the isolation region;
coating a resist layer over the ILD layer;
creating an opening in the resist layer;
etching away the ILD layer via the opening to expose the first and second S/D regions, wherein a recess having a depth of h is simultaneously produced in the isolation region;
stripping the resist layer;
depositing a spacer layer covering bottom and interior walls of the recess, and the exposed first and second S/D regions; and
etching back the spacer layer to form a spacer on each wall of the recess.

9. The method of claim 8 wherein after depositing the ILD layer, the method further comprises a polishing step to form a substantially even surface of the ILD layer.

10. The method of claim 8 wherein before depositing the ILD layer, the method further comprises depositing an etch stop layer in a blanket manner.

11. The method of claim 8 wherein the isolation region comprises an STI oxide embedded in a trench.

12. The method of claim 8 wherein the first and second S/D regions both have a predetermined junction depth.

13. The method of claim 8 wherein each of the first and second S/D regions further comprises a salicide layer.

14. The method of claim 8 wherein the ILD layer is composed of silicon oxide, and the spacer layer is composed of silicon nitride.
